(19) United States
(12) Patent Application Publication
(10) Pub. No.: US 2025/0266791 A1
(43) Pub. Date: Aug. 21, 2025

(54) Solar Cell Connector and String Process for Solar Cells

(71) Applicant: Maxeon Solar, Pte.Ltd., Singapore (SG)

(72) Inventors: Hongshuai Xu, Wuxi City (CN); Jianfang Si, Kunshan City (CN); Qiang Zhang, Jiangsu Province (CN); Mingchong Dai, Yantai City (CN); Jialin Shen, Changzhou City (CN)

(73) Assignee: Maxeon Solar, Pte.Ltd, Singapore (SG)

(21) Appl. No.: 18/443,321

(22) Filed: Feb. 16, 2024

(51) Int. Cl. H02S 40/34; H02S 30/10

(52) U.S. Cl. CPC H02S 40/34; H02S 30/10; H10F 77/215; H10F 77/93

(57) ABSTRACT

A solar cell connector is disclosed. The solar cell connector includes a first side that is configured to be coupled on a backside of a first solar cell, through a separate solar cell connector, to a first ribbon that is located on the backside of the first solar cell, and a second side that is configured to be coupled on the frontside of a second solar cell to a second ribbon that is located on the frontside of the second solar cell.

### TECHNICAL FIELD

Embodiments of the disclosure pertain to solar cell connectors, and more particularly to solar cell connectors that are used in a string process for solar cells.

### BACKGROUND

A solar cell string is a series-connected group of solar cells. Two conventional types of solar cell string technologies are shingle and multi busbar (MBB). Solar cell shingles are solar cells that can be overlaid like shingles on a roof to form electrical connections. MBB solar cells are solar cells that have a higher number of busbars (9 to 16 bus bars) for connecting solar cells than other solar cells (4, 5 or 6 busbars). A solar cell string can be formed using both shingle and MBB technologies. However, both technologies are expensive as they utilize high-cost silver to achieve high-level efficiency. In addition, when using these technologies, in order to provide gapless modules, part of the area of the solar cell is lost. Accordingly, aspects of the utilization of both conventional shingle and MBB technologies can be less than satisfactory.

### BRIEF DESCRIPTION OF THE DRAWINGS

FIG. 1A illustrates an exemplary operating environment of a photovoltaic module with stringed solar cells according to one embodiment.

FIG. 1B illustrates a part of a process of forming a solar cell string according to one embodiment.

FIG. 1C illustrates a part of a process of forming a solar cell string according to one embodiment.

FIG. 1D shows front and back views of parts of a solar cell that includes conductive connectors coupled to ribbons.

FIG. 1E illustrates a part of a process of forming a solar cell string according to one embodiment.

FIG. 1F shows a view of the connected portions of first and second solar cells of the solar cell string according to one embodiment.

FIG. 1G shows a closeup view of the connected portions of first and second solar cells of the solar cell string according to one embodiment.

FIG. 1H is a diagram of a side view of a conductive connector on the top surface of a second solar cell extending underneath the bottom surface of a first solar cell to make contact with a conductive connector on the bottom surface of the first solar cell.

FIG. 1I shows top and bottom views of a solar cell that is used to form a solar cell string according to one embodiment.

FIG. 1J illustrates a part of a process of forming a solar cell string according to one embodiment.

FIG. 1K illustrates a part of a process of forming a solar cell string according to one embodiment.

FIG. 2 shows a flow diagram of the process used to form a solar cell string according to one embodiment.

FIG. 3A shows a flowchart of a method of forming solar cell connectors according to one embodiment.

FIG. 3B shows a flowchart of a method of forming solar cell connectors according to one embodiment.

FIG. 4 shows a flowchart of a method of forming solar cell connectors according to one embodiment.

### DESCRIPTION OF THE EMBODIMENTS

It should be appreciated that although embodiments are described herein with reference to example solar cell connector implementations, the disclosure is applicable to solar cell connector implementations in general as well as other kinds of solar cell connector implementations. In the following description, numerous specific details are set forth, such as specific integration and material regimes, in order to provide a thorough understanding of embodiments of the present disclosure. It will be apparent to one skilled in the art that embodiments of the present disclosure may be practiced without these specific details. In other instances, well-known features, are not described in detail in order to not unnecessarily obscure embodiments of the present disclosure. Furthermore, it is to be appreciated that the various embodiments shown in the Figures are illustrative representations and are not necessarily drawn to scale.

Certain terminology may also be used in the following description for the purpose of reference only, and thus are not intended to be limiting. For example, terms such as “upper”, “lower”, “above”, and “below” refer to directions in the drawings to which reference is made. Terms such as “front”, “back”, “rear”, and “side” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

A solar cell string is a series-connected group of solar cells. Two conventional types of solar cell string technologies are shingle and multi busbar (MBB). Solar cell shingles are solar cells that can be overlaid like shingles on a roof to form electrical connections. MBB solar cells are solar cells that have a higher number of busbars (9 to 16 bus bars) for connecting solar cells than other solar cells (4, 5 or 6 busbars). A solar cell string can be formed using both shingle and MBB technologies. However, both technologies are expensive as they utilize high-cost silver to achieve high-level efficiency. In addition, when using these technologies, to provide gapless modules, part of the area of the solar cell is lost. Accordingly, aspects of the utilization of both conventional shingle and MBB technologies can be less than satisfactory.

A solar cell connector is disclosed herein that addresses the challenges of conventional approaches as described above. In one embodiment, the solar cell connector includes a first side that is configured to be coupled on a backside of a first solar cell, through a separate solar cell connector, to a first ribbon that is located on the backside of the first solar cell, and a second side that is configured to be coupled on the frontside of a second solar cell to a second ribbon that is located on the frontside of the second solar cell.

The structure, connection and material makeup of the solar cell connector helps to avoid the loss of photon collecting surface area of the solar cell while providing high level efficiency. This enables a generation of electron-hole pairs that otherwise would not be generated, such as from the additional light, that can be received because excessive loss of the photon collecting surface area of the solar cell is avoided. In one embodiment, this reduction in optical losses increases the efficiency of the solar cell such that more power can be supplied to loads.

### Solar Cell Connector and String Process for Solar Cells

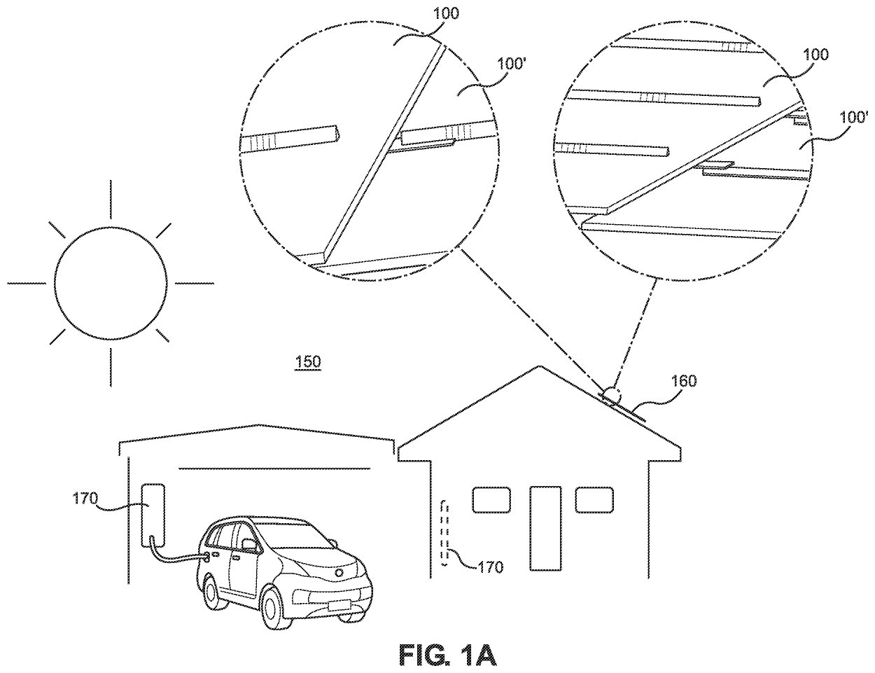

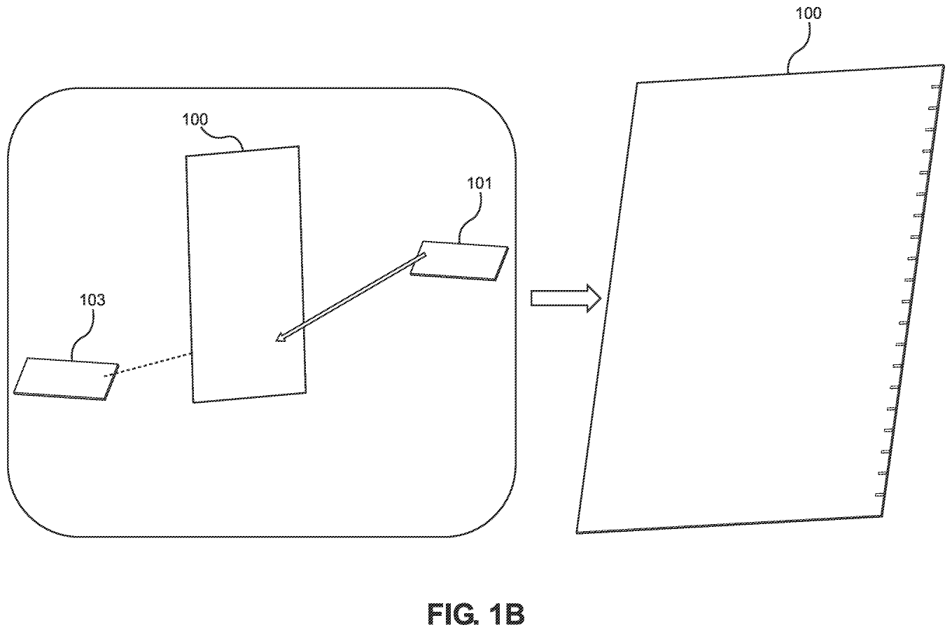

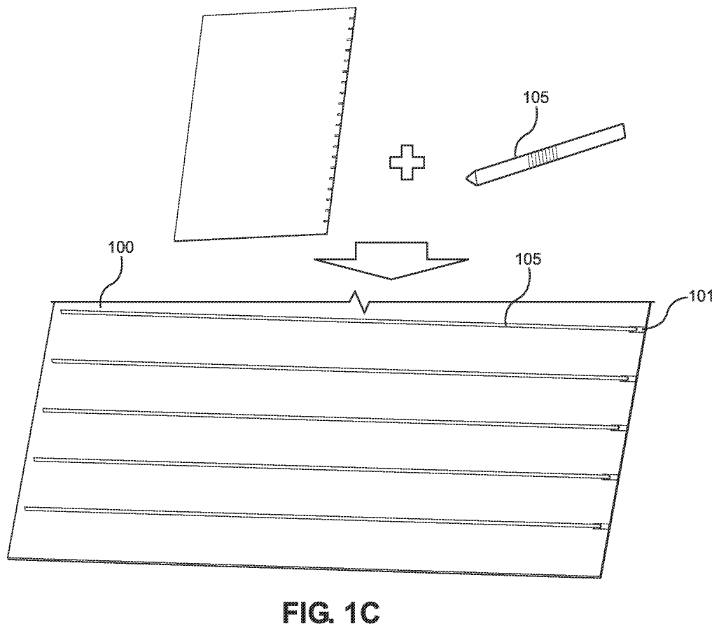

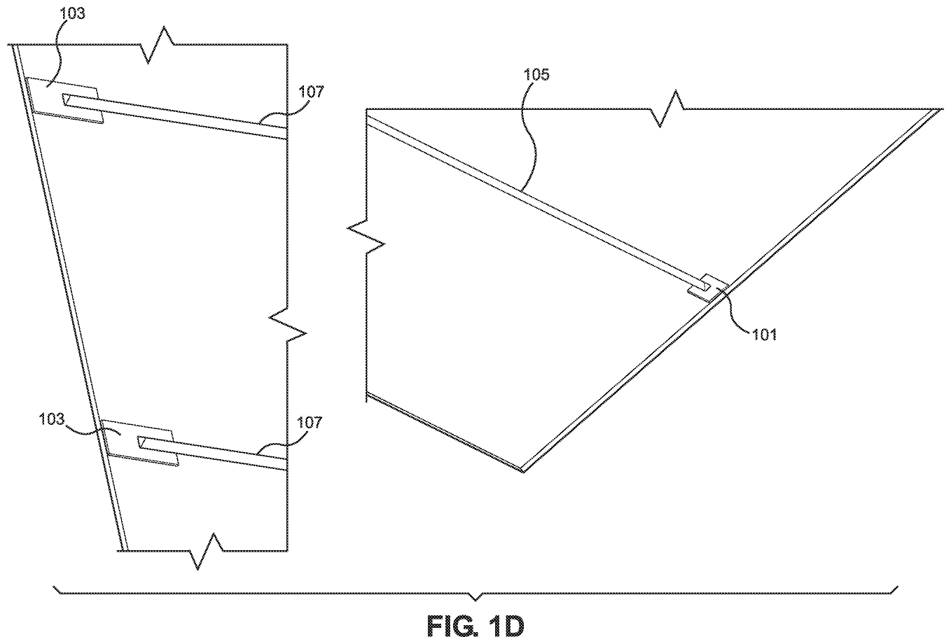

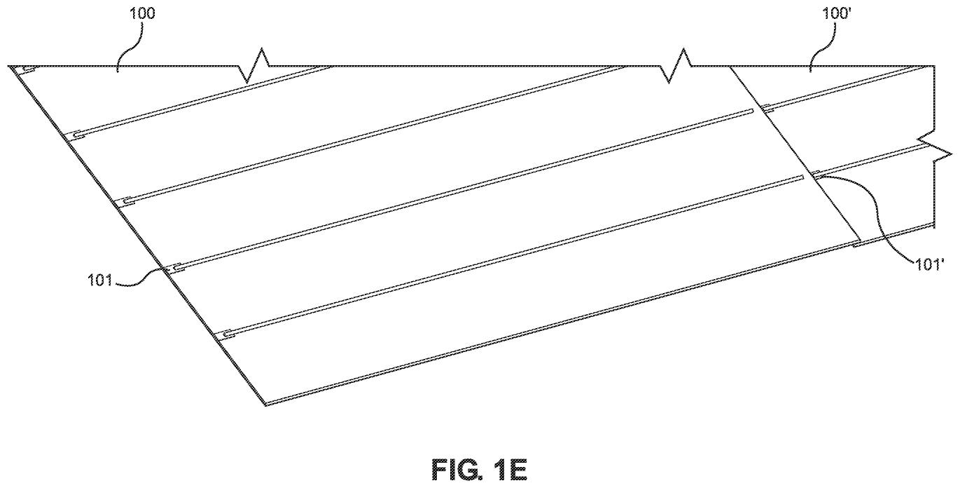

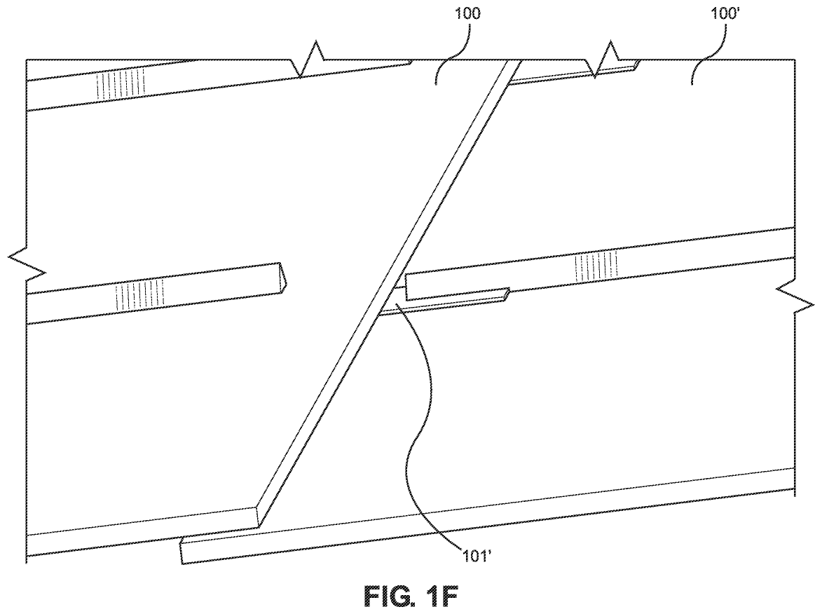

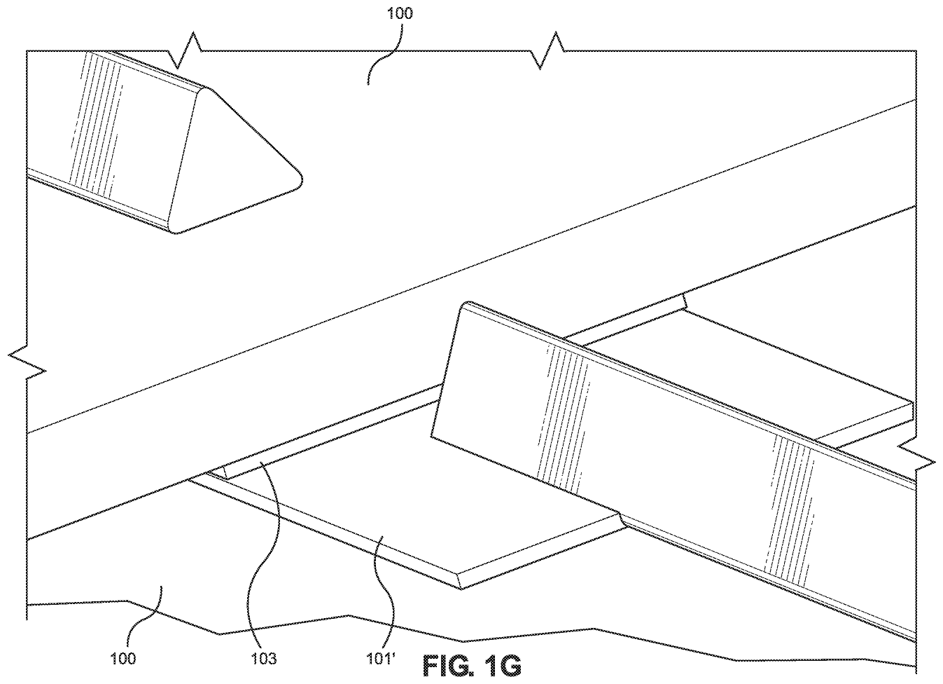

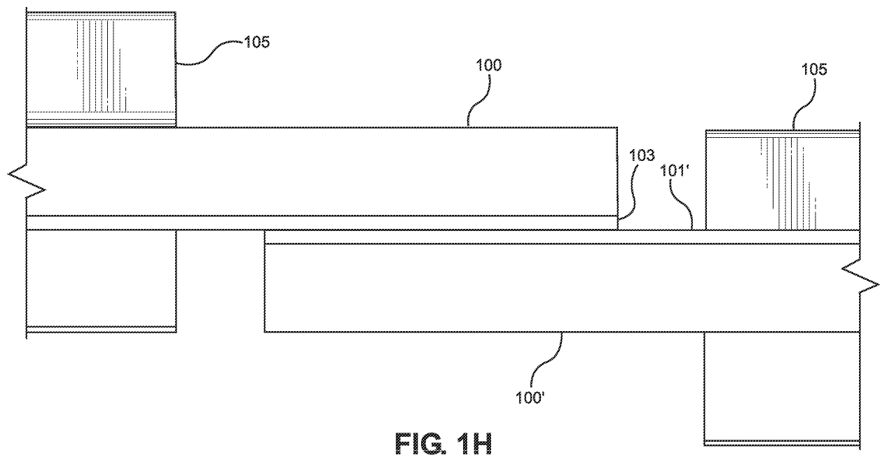

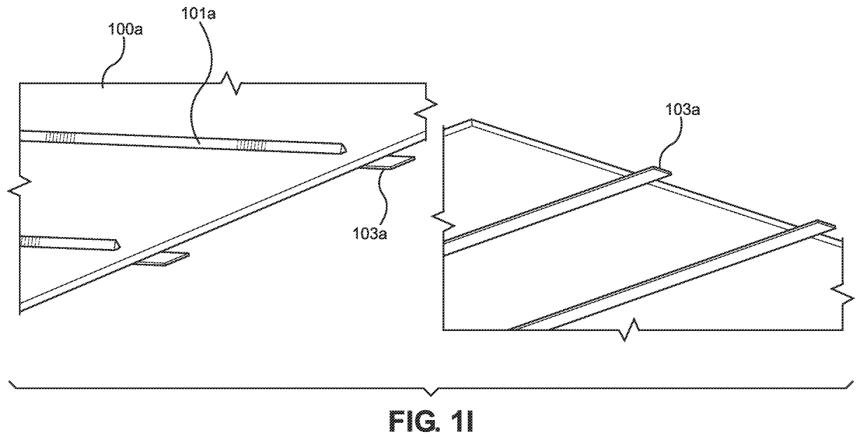

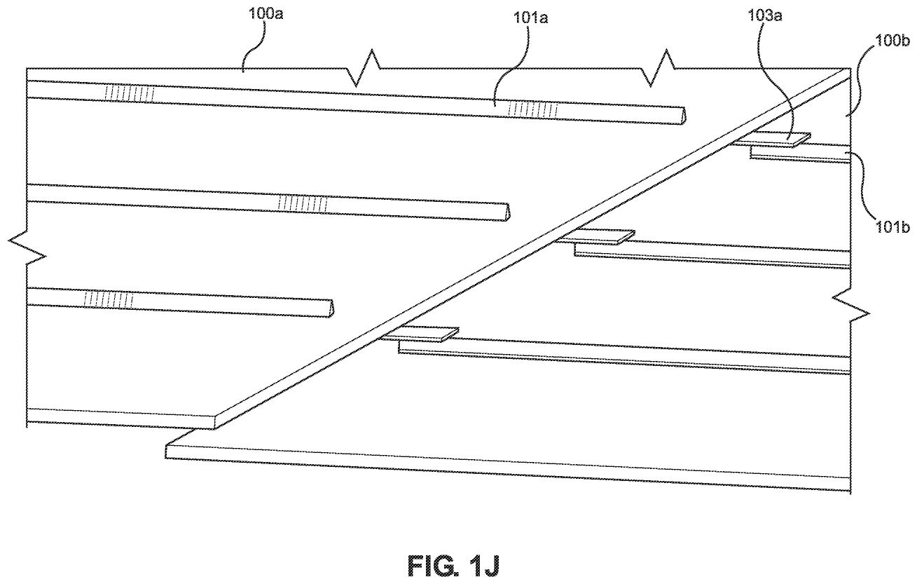

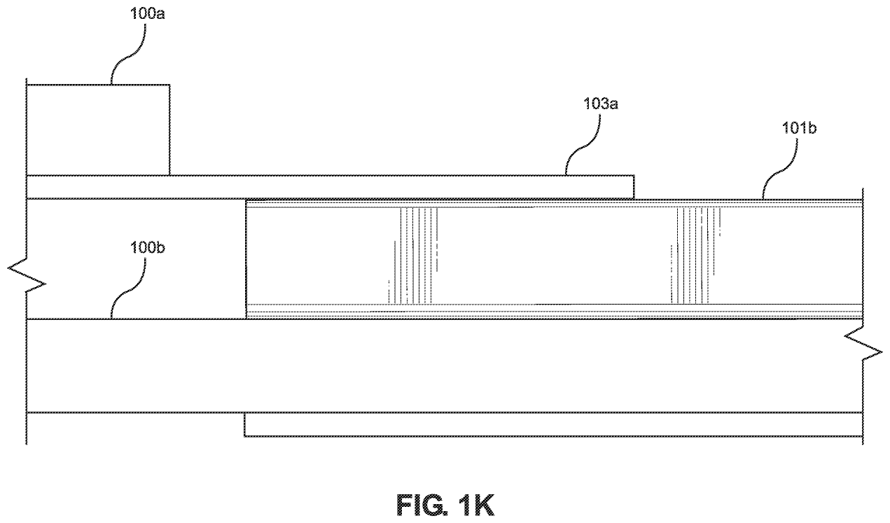

FIG. 1A illustrates an exemplary operating environment of a photovoltaic module with solar cells connected in a string according to one embodiment. FIG. 1A shows a location 150 that includes photovoltaic modules 160 that include solar cells 100 or 100′ (hereinafter “the solar cells” or “a solar cell” or “the solar cell”) that are connected using solar cell connectors configured as described herein. In one embodiment, the photovoltaic modules 160 utilize the electrical energy generated by the solar cells to supply the location 150 with electricity that is used to power appliances 170 that are used at the location 150.

FIGS. 1B-1H illustrate a process of forming a solar cell string according to one embodiment. FIG. 1B shows solar cell 100, metal strips 101, and metal strips 103. In FIG. 1B, the manner in which the metal strips 101 and the metal strips 103 are coupled to the solar cell 100 is illustrated. FIG. 1B shows that the metal strips 101 are coupled to a first edge of the solar cell 100 on the top surface of the solar cell 100. And the metal strips 103 are coupled to a second edge of the solar cell 100 on the bottom surface of the solar cell 100. In one embodiment, the metal strips 101 are aligned along the first edge of the solar cell 100 on the top surface of the solar cell 100 in a line that extends from a first side of the solar cell 100 to a second side of the solar cell 100. Moreover, in one embodiment, first edges of the metal strips 101 are aligned to be coincident the first edge of the solar cell 100 and second edges of the metal strips 101 extend in the opposite direction away from the first edge of the solar cell 100. In one embodiment, the metal strips 103 are aligned along the second edge of the solar cell 100 on the bottom surface of the solar cell 100 in a line that extends from a first side of the solar cell 100 to a second side of the solar cell 100. Moreover, in one embodiment, first edges of the metal strips 103 are aligned to be coincident with the back edge of the solar cell 100 and second edges of the metal strips 103 are positioned to extend away from the back edge of the solar cell 100 (not shown in FIG. 1B).

FIG. 1C shows how ribbons 105 are positioned on the top surface of the solar cell 100 according to one embodiment. Referring to FIG. 1C, a first end of the ribbons 105 are coupled to the top surface of the metal strips 101 that are located on the top surface of the solar cell 100. In one embodiment, the ribbons 105 extend in a direction that corresponds to the direction in which the metal strips 101 to which they are coupled extend. In one embodiment, the ribbons 105 extend to a point short of the edge of the top surface of the solar cell 100 that is opposite to that which the metal strips 101 are attached. In one embodiment, the distance between the end of the ribbon 105 and the edge of the top surface of the solar cell 100 that is opposite to that which the metal strips 101 are attached can vary.

FIG. 1D shows the manner in which ribbons are positioned on the top and back surfaces of the solar cell 100 with respect to metal strips attached thereto according to one embodiment. Referring to FIG. 1D, ribbons 107 on the back surface of the solar cell 100 are coupled to the top surface of the metal strips 103 that are on the back surface of the solar cell 100 in a manner that is similar to that in which the ribbons 105 on the front surface of the solar cell 100 are coupled to the top surface of the metal strips 101 that are on the front surface of the solar cell 100. In one embodiment, the ribbons 107 on the back surface of the solar cell 100 extend in a direction that corresponds to the direction in which the metal strips 103 that are on the back surface of the solar cell 100 to which they are coupled extend.

FIG. 1E shows the manner in which a first solar cell 100 and a second solar cell 100′ are coupled according to one embodiment. Referring to FIG. 1E, the first solar cell 100 is coupled to the second solar cell 100′ by aligning the metal strips 101′ on the top surface of the second solar cell 100′ with the metal strips 103 on the bottom surface of the first solar cell 100.

FIG. IF shows a view of the metal strip 101′ on the top surface of the second solar cell 100′ extending underneath the bottom surface of the first solar cell 100 to make contact with the metal strip (not shown) on the bottom surface of the first solar cell 100.

FIG. 1G shows a closeup view of the metal strip 101′ on the top surface of the second solar cell 101′ extending underneath the bottom surface of the first solar cell 100 to make contact with the metal strip 103 on the bottom surface of the first solar cell 100.

FIG. 1H is a diagram of a side view of the metal strip 101′ on the top surface of the second solar cell 100′ extending underneath the bottom surface of the first solar cell 100 to make contact with the metal strip 103 on the bottom surface of the first solar panel 100.

FIGS. 1I-1J illustrate another process of forming a solar cell string according to one embodiment. FIGS. 1I-1J illustrate the manner in which a first solar cell 100a (FIGS. 1I-1K) and a second solar cell 100b (FIGS. 1J-1K) are coupled according to one embodiment. Referring to FIG. 1I, the bottom side of the solar panel 100a includes a plurality of strips 103a that extend from a location offset from a first bottom side edge (not shown) of the solar panel 100a to a point beyond a second bottom side edge of the solar panel 100a. In addition, in one embodiment, the top side of the solar panel 100 includes a plurality of triangular ribbons 101a that extend from a location offset from the first top side edge of the solar panel 100a to a point short of the second top side edge of the solar panel 100a. Referring to FIG. 1J, in one embodiment, to couple the first solar cell 100a and the second solar cell 100b in a string, the plurality of strips 103a that extend from a location offset from a first bottom side edge of the first solar panel 100a to a point beyond a second bottom side edge of the first solar cell 100a are positioned on the triangular ribbons 101b of the second solar cell 100b.

FIG. 1K is a diagram of a side view of first solar cell 100a and second solar cell 100b that are connected in a string according to one embodiment. Referring to FIG. 1K, ribbon 103a extends beyond the edge of the bottom side of the solar cell 100a and is coupled to the top of the triangular ribbon 101b that is located on the top side of the solar panel 100b to effect the coupling of the solar cell 100a to the solar cell 100b in a string.

### Operation

Referring to FIG. 1A, in operation, light contacts the front surface of solar cells of a photovoltaic module that are stringed together as is described herein. The structure, connection and material makeup of the metal strips helps to avoid the loss of photon collecting surface area of the solar cell while providing high level efficiency. This enables a generation of electron-hole pairs that otherwise would not be generated, such as from the additional light, that can be received because of excessive loss of photon collecting surface area of the solar cell is avoided. In one embodiment, this reduction in optical losses increases the efficiency of the solar cell such that more power can be supplied to loads.

### Process of Forming Solar Cell String

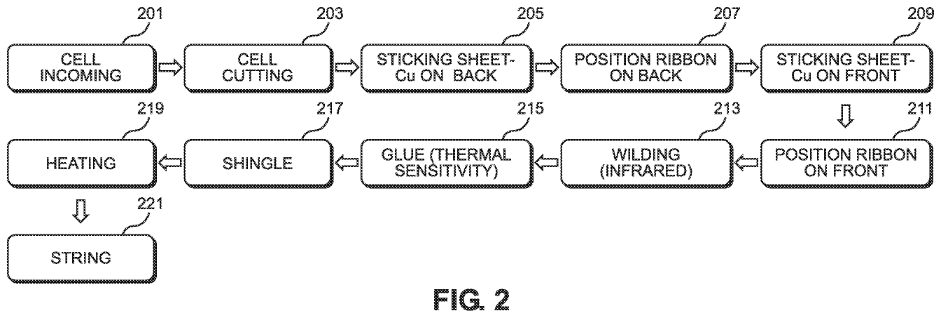

FIG. 2 shows a flow diagram of the process used to form a solar cell string according to one embodiment. Referring to FIG. 2, at 201 incoming solar cells are received. At 203, cell cutting operations are executed. At 205, the sticking of sheet copper on the back of the solar cell is performed. In other embodiments, conductive material other than copper can be used. At 207, the positioning of a ribbon on the back of the solar cell is performed. At 209, the sticking of sheet copper on the front of the solar cell is performed. In other embodiments, conductive material other than sheet copper can be used. At 211, the positioning of a ribbon on the front of the solar cell is performed. At 213, the welding of the solar cell is performed. At 215, the gluing of the solar cell is performed. At 217 the solar cells are shingled. At 219, the solar cells are heated. At 221, the solar cell string is formed.

### Method of Forming a Solar Cell Connector

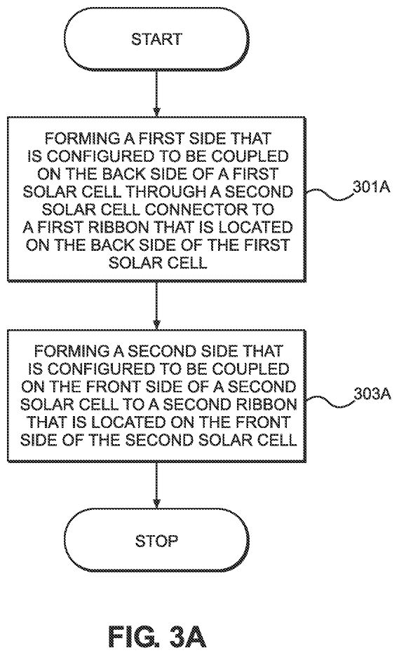

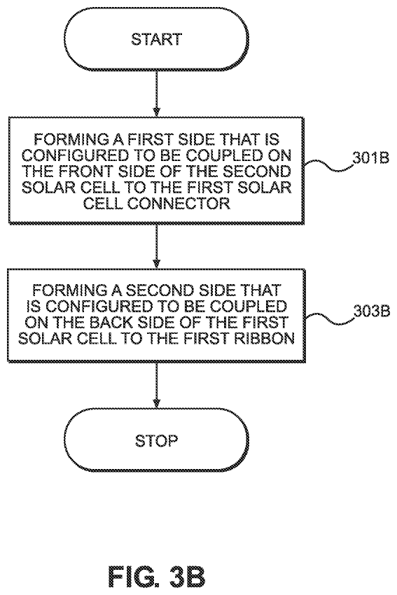

FIGS. 3A and 3B show flowcharts of methods of forming a first solar cell connector and a second solar cell respectively. It should be noted that, in one embodiment, the blocks of the flowcharts of FIGS. 3A and 3B are exemplary. FIG. 3A shows a method of forming a first solar cell connector according to one embodiment. In one embodiment, blocks not shown in FIG. 3A may be used. In one embodiment, the method of forming a first solar cell connector includes at 301 forming a first side that is configured to be coupled on a backside of a first solar cell, through a separate solar cell connector, to a first ribbon that is located on the backside of the first solar cell, and, at 303 forming a second side that is configured to be coupled on the frontside of a second solar cell to a second ribbon that is located on the frontside of the second solar cell.

FIG. 3B shows a method of forming a second solar cell connector according to one embodiment. In one embodiment, blocks not shown in FIG. 3B may be used. In one embodiment, the method of forming a second solar cell connector includes at 301B, forming a first side that is configured to be coupled on the frontside of the second solar cell to the first solar cell connector, and, at 303B forming a second side that is configured to be coupled on the backside of the first solar cell to the first ribbon.

In one embodiment, the second solar cell connector contacts the bottom surface of the first ribbon. In one embodiment, the first ribbon and the second ribbon have a uniform geometry. In one embodiment, the first ribbon and the second ribbon have a triangular or oval geometry. In one embodiment, the solar cell connectors have a thickness of 0.001 mm-0.2 mm. In one embodiment, the solar cell connectors include a flat conductive sheet. In one embodiment, the flat conductive sheet is copper.

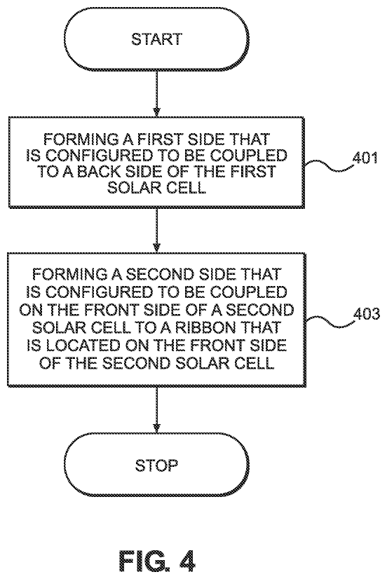

FIG. 4A shows a method of forming a solar cell connector according to one embodiment. Referring to FIG. 4, at 401, forming a first side that is configured to be coupled to a backside of the first solar cell, and, at 403, forming a second side that is configured to be coupled on the frontside of a second solar cell to a ribbon that is located on the frontside of the second solar cell.

In one embodiment, a top surface of the ribbon contacts the second side of the solar cell connector. In one embodiment, the solar cell connector and the ribbon have a uniform geometry. In one embodiment, the solar cell connector is flat and the ribbon is triangular or oval. In one embodiment, the solar cell connector has a thickness of 0.001 mm-0.2 mm. In one embodiment, the solar cell connector includes a flat conductive sheet. In one embodiment, the flat conductive sheet is copper.

Although specific embodiments have been described above, these embodiments are not intended to limit the scope of the present disclosure, even where only a single embodiment is described with respect to a particular feature. Examples of features provided in the disclosure are intended to be illustrative rather than restrictive unless stated otherwise. The above description is intended to cover such alternatives, modifications, and equivalents as would be apparent to a person skilled in the art having the benefit of the present disclosure. The scope of the present disclosure includes any feature or combination of features disclosed herein (either explicitly or implicitly), or any generalization thereof, whether or not it mitigates any or all of the problems addressed herein. Accordingly, new claims may be formulated during prosecution of the present application (or an application claiming priority thereto) to any such combination of features. In particular, with reference to the appended claims, features from dependent claims may be combined with those of the independent claims and features from respective independent claims may be combined in any appropriate manner and not merely in the specific combinations enumerated in the appended claims.

The various features of the different embodiments may be variously combined with some features included and others excluded to suit a variety of different applications.

What is claimed is:

1. Solar cell connectors, comprising:
a first solar cell connector comprising:
a first side that is configured to be coupled on a backside of a first solar cell, through a second solar cell connector, to a first ribbon that is located on the backside of the first solar cell; and
a second side that is configured to be coupled on a frontside of a second solar cell to a second ribbon that is located on the frontside of the second solar cell.

2. The solar cell connectors of claim 1, further comprising:
the second solar cell connector that includes:
a first side that is configured to be coupled on the frontside of the second solar cell to the first solar cell connector; and
a second side that is configured to be coupled on the backside of the first solar cell to the first ribbon.

3. The solar cell connectors of claim 1, wherein the second solar cell connector contacts a bottom surface of the first ribbon.

4. The solar cell connectors of claim 1, wherein the first ribbon and the second ribbon have a uniform geometry.

5. The solar cell connectors of claim 1, wherein the first ribbon and the second ribbon have a triangular or oval geometry.

6. The solar cell connectors of claim 1, wherein the solar cell connectors have a thickness of 0.001 mm-0.2 mm.

7. The solar cell connectors of claim 1, wherein the solar cell connectors include a flat conductive sheet.

8. The solar cell connectors of claim 7, wherein the flat conductive sheet is copper.

9. A photovoltaic module, comprising:
a frame;
a plurality of solar cells coupled to the frame; and
solar cell connectors connecting the plurality of solar cells, including:
first solar cell connectors including:
a first side that is configured to be coupled on a backside of a first solar cell, through a second solar cell connector, to a first ribbon that is located on the backside of the first solar cell; and
a second side that is configured to be coupled on the frontside of a second solar cell to a second ribbon that is located on a frontside of the second solar cell.

10. The photovoltaic module of claim 9, further comprising:
the second solar cell connector including:
a first side that is configured to be coupled on a frontside of the second solar cell to the first solar cell connector; and
a second side that is configured to be coupled on the backside of the first solar cell to the first ribbon.

11. The photovoltaic module of claim 9, wherein the second solar cell connector contacts a bottom surface of the first ribbon.

12. The photovoltaic module of claim 9, wherein the first ribbon and the second ribbon have a uniform geometry.

13. The photovoltaic module of claim 9, wherein the first ribbon and the second ribbon have a triangular or oval geometry.

14. The photovoltaic module of claim 9, wherein the solar cell connector has a thickness of 0.001 mm-0.2 mm.

15. The photovoltaic module of claim 9, wherein the solar cell connector includes a flat conductive sheet.

16. The photovoltaic module of claim 15, wherein the flat conductive sheet is copper.

17. A method of forming solar cell connectors, comprising:
forming a first solar cell connector comprising:
forming a first side that is configured to be coupled on a backside of a first solar cell, through a second solar cell connector, to a first ribbon that is located on the backside of the first solar cell; and
forming a second side that is configured to be coupled on a frontside of a second solar cell to a second ribbon that is located on the frontside of the second solar cell.

18. The method of forming solar cell connectors of claim 17, further comprising:
forming a second solar cell connector comprising:
forming a first side that is configured to be coupled on a frontside of the second solar cell to the first solar cell connector; and
forming a second side that is configured to be coupled on the backside of the first solar cell to the first ribbon.

19. The method of forming the solar cell connector of claim 17, wherein the second solar cell connector contacts the bottom surface of the first ribbon.

20. The method of forming the solar cell connector of claim 17, wherein the first ribbon and the second ribbon have a uniform geometry.
